(19) United States
(12) Patent Application Publication
(10) Pub. No.: US 2022/0349919 A1
(43) Pub. Date: Nov. 3, 2022

(54) PROBE INSTALLATION CIRCUIT BOARD AND PROBE DEVICE FOR PROBE CARD

(71) Applicant: MPI CORPORATION, CHU-PEI CITY (TW)

(72) Inventors: YU-SHAN HU, CHU-PEI CITY (TW); SHAO-LUN WEI, CHU-PEI CITY (TW); YI-LUNG LEE, CHU-PEI CITY (TW); YU-WEN CHOU, CHU-PEI CITY (TW)

(73) Assignee: MPI CORPORATION, CHU-PEI CITY (TW)

(21) Appl. No.: 17/727,216

(22) Filed: Apr. 22, 2022

(30) Foreign Application Priority Data
Apr. 27, 2021 (TW) 110115159
Jan. 5, 2022 (TW) 111100453

(51) Int. Cl. G01R 1/073

(52) U.S. Cl. CPC G01R 1/07342; G01R 1/07328

(57) ABSTRACT

A probe installation circuit board includes an insulating layer provided on upper and lower surfaces thereof with a trace structure including two grounding traces and a signal trace located therebetween, and a grounding layer. Each grounding trace is connected with the grounding layer by at least one conductive via including a through hole penetrating through the grounding trace and the insulating layer, and a conductive layer disposed therein to electrically connect the grounding trace and layer. The signal trace and the conductive layers are made of a metal material. The grounding layer and traces are made of another metal material. A probe device includes the circuit board and three probes disposed on the traces respectively. The present invention is capable of thin copper traces and lowered trace surface roughness, easy in control of trace distance, width and thickness, and beneficial to achieve the fine pitch requirement.

### BACKGROUND OF THE INVENTION

### 1. Field of the Invention

The present invention relates generally to probe cards and more particularly, to a probe installation circuit board for a probe card, and a probe device including the probe installation circuit board.

### 2. Description of the Related Art

In a conventional membrane probe card, a flexible membrane circuit board is adopted to serve as a probe head. The flexible membrane circuit board is made by drilling, electroplating, photolithography and surface treatment processes from a flexible substrate 10 whose cross section is configured as shown in FIG. 1A. The cross section of the flexible membrane circuit board 11 is configured as shown in FIG. 1B. Specifically speaking, the flexible substrate 10 is a flexible copper clad laminate (also referred to as ‘FCCL’ hereinafter), which includes a membranous insulating layer 12 made of polyimide (also referred to as ‘PI’ hereinafter) or liquid crystal polymer (also referred to as ‘LCP’ hereinafter), and upper and lower copper layers 13 and 14 disposed on upper and lower surfaces of the insulating layer 12 respectively. The aforementioned drilling and electroplating processes provide the flexible membrane circuit board 11 with a plurality of plated through holes 15. Each plated through hole 15 is plated on the inner wall thereof with copper to electrically connect the upper and lower copper layers 13 and 14 with each other. The aforementioned photolithography process defines the flexible membrane circuit board 11 with a plurality of grounding traces 16 including the plated through hole 15, and a plurality of signal traces 17 including no such plated through hole 15, for disposing grounding probes and signal probes (not shown), such as bumps formed on the flexible membrane circuit board 11, at appropriate positions on the grounding traces 16 and signal traces 17 respectively. The aforementioned surface treatment process uses electroless nickel immersion gold (also referred to as ‘ENIG’ hereinafter) to make the copper surface of each trace 16 or 17 covered by a protective layer 18 including a nickel layer and a gold layer for preventing copper from oxidation and providing weld interface.

However, it is practically hard to control the quantity of copper etched in the aforementioned photolithography process, so that it is hard to control the widths and thicknesses of the traces 16 and 17, and each trace 16 or 17 is practically shaped with narrower top and wider bottom, like the trace 17 shown in FIG. 2. Such trace shape will affect the impedance matching of the grounding trace 16 and the signal trace 17. Besides, the photolithography process also makes the copper surface rough, thereby affecting transmission quality of high frequency signal. In addition, because the widths of the traces 16 and 17 are hard to control, it will be difficult for the probes to meet the requirement of fine pitch. As shown in FIG. 2, in practice the copper layer of each trace 16 or 17 includes the original copper layer 13 of the flexible substrate 10 and another copper layer 19 formed from the copper produced in the above-described electroplating process and partially removed by the above-described photolithography process. Therefore, it is hard to form thin copper traces, and the copper layer 19 is different in thickness from the copper located on the inner wall of the plated through hole 15 in that the copper located on the inner wall is relatively thicker. Furthermore, the protective layer 18 provided on the surface of each trace 16 or 17 is generally made by a material having a relatively higher electric resistivity. Therefore, when transmitting high frequency signal, the traces 16 and 17 are liable to provide a relatively lower electric conductivity because of skin effect. However, if the protective layer 18 is omitted under the consideration of high frequency, the naked copper will have oxidation problem.

### SUMMARY OF THE INVENTION

The present invention has been accomplished in view of the above-noted circumstances. It is a primary objective of the present invention to provide probe installation circuit board and probe device for a probe card, which can solve at least one problem of the prior art.

To attain the above objective, the present invention provides a probe installation circuit board for a probe card, which includes an insulating layer, a grounding layer disposed on a lower surface of the insulating layer, a trace structure disposed on an upper surface of the insulating layer, and a plurality of conductive vias. The trace structure includes two grounding traces, and a signal trace located between the two grounding traces. Each of the grounding traces is connected with the grounding layer by at least one of the conductive vias. Each of the conductive vias includes a through hole penetrating through the grounding trace and the insulating layer, and a conductive layer disposed in the through hole to electrically connect the grounding trace with the grounding layer. The signal trace and the conductive layers of the conductive vias are made of a first metal material. The grounding layer and the grounding traces are made of a second metal material different from the first metal material.

To attain the above objective, the present invention provides a probe device which includes the aforementioned probe installation circuit board, and three probes disposed on the grounding traces and the signal trace respectively. An end of each of the grounding traces and the signal trace is electrically connected with the respective probe. The other end of each of the grounding traces and the signal trace is electrically connected with a tester.

As a result, the first metal material may be a metallic conductor having great oxidation resistance, such as gold, platinum, palladium or rhodium, so that the signal trace and the conductive layers of the conductive vias have no need of surface treatment by nickel immersion gold and no reduction in width or thickness caused by etching in the manufacturing process. The original copper layer of a substrate can be directly used to form the grounding layer and the grounding traces, so that no additional copper layer should be made by electroplating. Therefore, thin copper traces can be formed. Besides, the signal trace and the conductive layers of the conductive vias can be formed by electroplating in grooves provided with specific widths at specific positions by photoresist produced in the photolithography process, such that it consumes low quantity of the first metal material and thus cost-saving, and it is easy to control the positions, widths and thicknesses of the signal trace and the conductive layers of the conductive vias and bring low surface roughness. In addition, by controlling the depth of the grooves formed by the photoresist, the signal trace can be provided with small aspect ratio of depth to width, thereby beneficial to achieve the requirement of fine pitch.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1A is a schematic sectional view of a conventional flexible substrate;

FIG. 1B is a schematic sectional view of a conventional flexible membrane circuit board;

FIG. 2 is a partial schematic view of the flexible membrane circuit board shown in FIG. 1B;

FIG. 3 is a schematic top view of a probe installation circuit board for a probe card according to a first preferred embodiment of the present invention, wherein six probes and a tester are also schematically shown;

FIG. 4 is a partial schematic sectional view of the probe installation circuit board for the probe card according to the first preferred embodiment of the present invention;

FIG. 5, FIG. 6 and FIG. 7 are partial schematic sectional views of probe installation circuit boards for probe cards according to second, third and fourth preferred embodiments of the present invention respectively; and

FIG. 8 is a schematic perspective cut-off view of a probe device adopting the probe installation circuit board as shown in FIG. 5.

### DETAILED DESCRIPTION OF THE INVENTION

First of all, it is to be mentioned that same reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

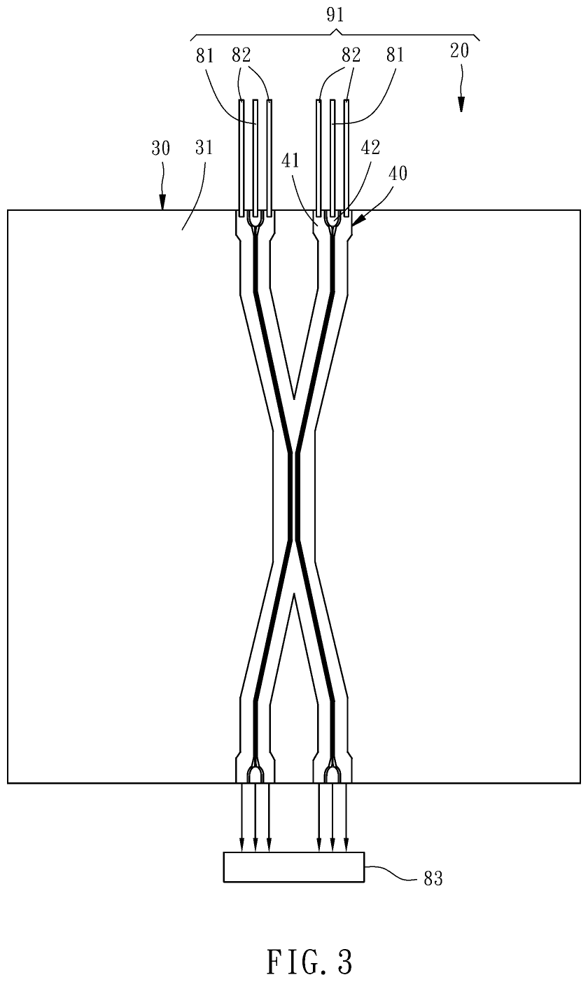

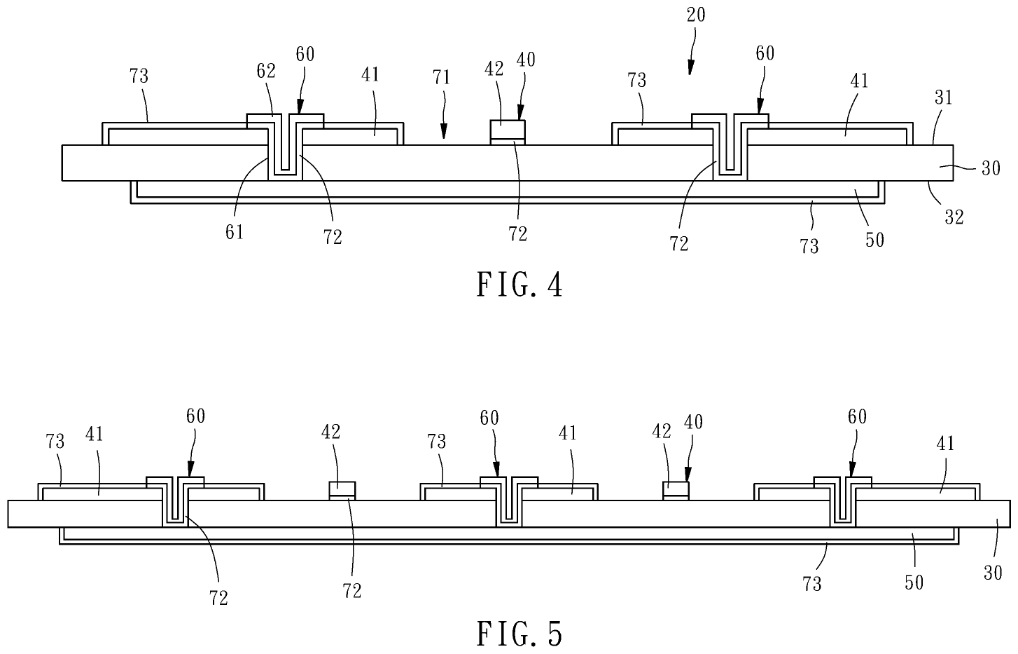

Referring to FIG. 3 and FIG. 4, a probe installation circuit board 20 for a probe card according to a first preferred embodiment of the present invention primarily comprises an insulating layer 30, a trace structure 40 and a grounding layer 50 disposed on upper and lower surfaces 31 and 32 of the insulating layer 30 respectively, and a plurality of conductive vias 60 connecting the trace structure 40 with the grounding layer 50. The appearance of the top surface of the probe installation circuit board 20 may, but unlimited to, be approximately configured as shown in FIG. 3. The primary technical features of the present invention lie in the trace structure 40 for being electrically connected with probes 81 and 82, and the conductive vias 60. For simplifying the figures, the conductive vias 60 are not shown in FIG. 3, and the probe installation circuit board 20 is partially and schematically shown in FIG. 4, for the convenience of illustrating the characteristics of the trace structure 40 and the conductive vias 60.

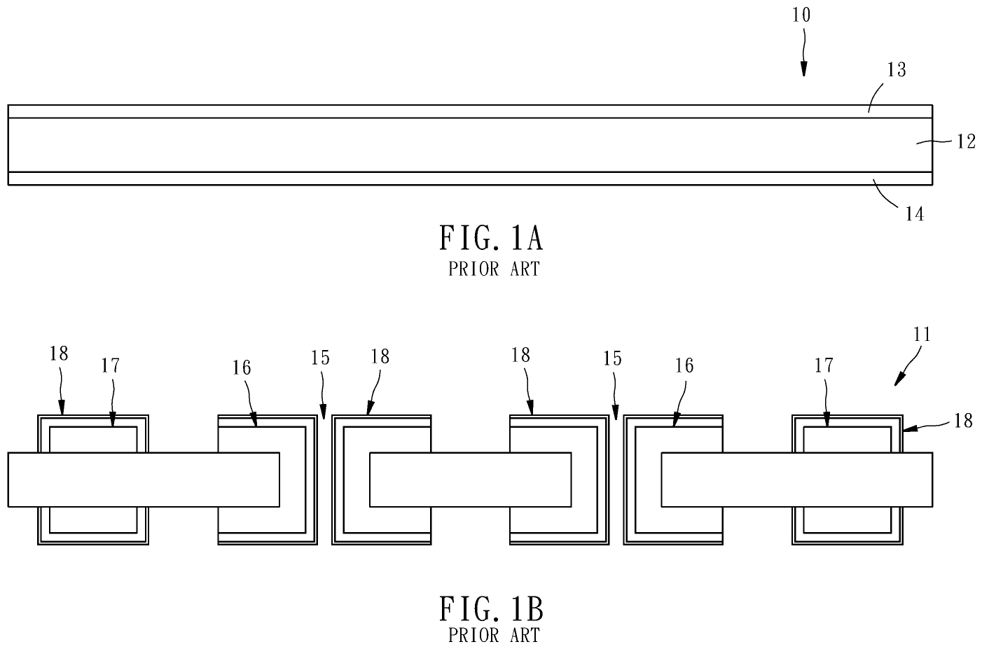

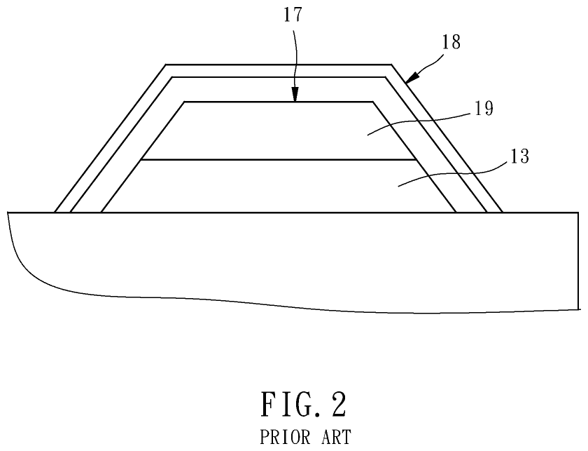

In this embodiment, the insulating layer 30 is a flexible board, which means the probe installation circuit board 20 in this embodiment is a flexible circuit board, but the present invention is unlimited thereto. In fact, the probe installation circuit board 20 in this embodiment may be made by etching, laser drilling, physical vapor deposition (also referred to as ‘PVD’ hereinafter), photolithography and electroplating processes from the flexible substrate 10 mentioned in the description of the related art as shown in FIG. 1A.

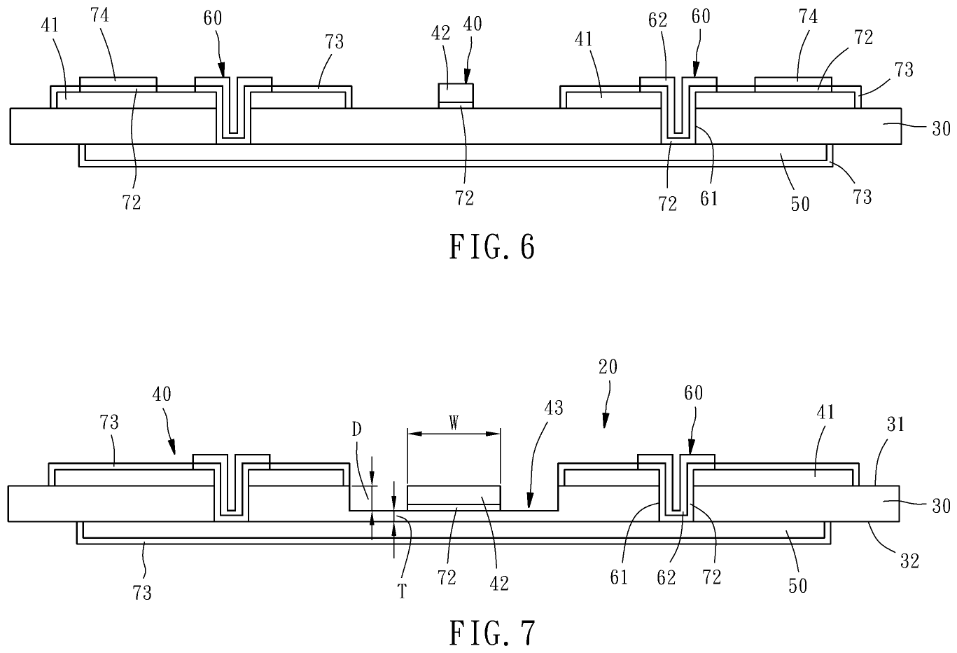

As shown in FIG. 3 and FIG. 4, the trace structure 40 includes two grounding traces 41, and a signal trace 42 located between the two grounding traces 41. The signal trace 42 is adapted to be connected with a signal probe 81. Each of the grounding traces 41 is adapted to be connected with a grounding probe 82. As a result, the probe installation circuit board 20 and the probes 81 and 82 compose a probe device 91. For example, the probes 81 and 82 may, but unlimited to, be respectively fixed by welding at free ends of the signal trace 42 and the grounding traces 41 located adjacent to an edge of the insulating layer 30, such as the end portions of the grounding traces 41 and the signal trace 42 located at the top edge of the probe installation circuit board 20 shown in FIG. 3, so that the probes 81 and 82 are adapted to probe a device under test (not shown). In addition, the probes 81 and 82 may extend toward free ends located away from the edge of the insulating layer 30 for a distance for being fixed to the signal trace 42 and the grounding traces 41 by welding. Specifically speaking, the probes 81 and 82 in this embodiment are cantilever probes. The probes 81 and 82 are partially fixed to an end of the grounding traces 41 and the signal trace 42 respectively, and partially extend out of the probe installation circuit board 20 transversely, i.e. extend approximately parallel to the probe installation circuit board 20. The signal trace 42 and grounding traces 41, and the probes 81 and 82 fixed to an end thereof by welding, are electrically connected with each other respectively. The other ends of the grounding traces 41 and signal trace 42 are adapted to be electrically connected to a tester 83, so that test signal can be transmitted between the probes 81 and 82 and the tester 83. It should be mentioned here that the configuration shown in FIG. 4 with only single one signal trace 42 and two grounding traces 41 located by two opposite sides thereof is taken as an example for illustration. However, the trace structure 40 may include more grounding traces 41 and signal traces 42, and every signal trace 42 is located between two grounding traces 41 for achieving great impedance matching effect. For example, the trace structure 40 in a second preferred embodiment of the present invention as shown in FIG. 5 includes three grounding traces 41, and two signal traces 42 located between the three grounding traces 41.

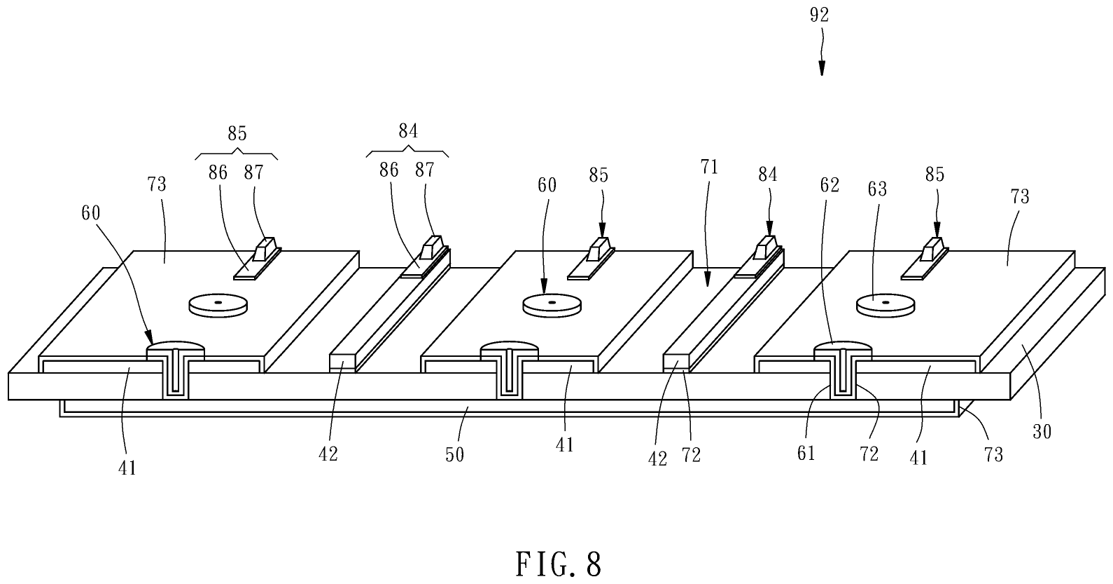

In addition, the probes in the present invention are unlimited to the aforementioned cantilever probes 81 and 82, but may be the signal probes 84 and grounding probes 85 as shown in FIG. 8 for example. A probe device 92 is partially and schematically shown in FIG. 8. The probe device 92 is composed of the probe installation circuit board 20 as shown in FIG. 5 and five probes 84 and 85. Each of the probes 84 and 85 includes a base 86 fixed to an oxidation resistant layer 73 located on the grounding trace 41 or fixed to the signal trace 42, and a pillar tip 87 extending from the base 86 vertically, i.e. approximately extending perpendicularly to the probe installation circuit board 20. The tip-shaped probes 84 and 85 as shown in FIG. 8 may be directly formed by electroplating on the oxidation resistant layers 73 located on the grounding traces 41 and the signal trace 42 by microelectromechanical system (MEMS) manufacturing process. Alternatively, the probe installation circuit board 20 and the probes 84 and 85 may be manufactured separately, and thereafter the probes 84 and 85 may be fixed to the oxidation resistant layers 73 located on the grounding traces 41 and the signal trace 42 by welding. Alternatively, the probe installation circuit board 20 may be provided with pillar-shaped structures fixed on the oxidation resistant layers 73 located on the grounding traces 41 and the signal trace 42, and then the pillar-shaped structures are formed into the probes 84 and 85 by etching.

As shown in FIG. 4 and FIG. 5, the grounding layer 50 is a large-area metal layer directly disposed on the lower surface 32 of the insulating layer 30, and the grounding traces 41 are small-area metal layers directly disposed on the upper surface 31 of the insulating layer 30 and separated from each other. Each of the grounding traces 41 is connected with the grounding layer 50 by at least one of the conductive vias 60, which means a grounding trace 41 may be electrically connected with the grounding layer 50 by one or more conductive vias 60 distributed at intervals. Secondary, each of the conductive vias 60 includes a through hole 61 and a conductive layer 62. A part of the through hole 61, which penetrates through the grounding trace 41, is formed by the aforementioned etching process, which means the partial grounding trace 41 located correspondingly to the through hole 61 is removed by etching. Then, another part of the through hole 61, which penetrates through the insulating layer 30 but not penetrates through the grounding layer 50, is formed by the aforementioned laser drilling process. The conductive layer 62 is disposed in the through hole 61 and on the partial grounding trace 41 located around the through hole 61, thereby electrically connecting the grounding trace 41 with the grounding layer 50.

The aforementioned etching process also provides a groove 71 between every two adjacent grounding traces 41 for disposing the signal trace 42. The width of the groove 71 is smaller than the width of the grounding trace 41 and larger than the width of the signal trace 42. The signal trace 42 and the conductive layers 62 of the conductive vias 60 are made of a first metal material by electroplating in grooves (not shown) formed by photoresist produced in the above-described photolithography process. The grounding layer 50 and the grounding traces 41 are made of a second metal material different from the first metal material. For example, the original copper layer of the aforementioned flexible substrate 10 may be directly used to form the grounding layer 50 and the grounding traces 41, which means the second metal material is copper. However, the second metal material may be other materials having high electric conductivity, such as nickel, aluminum, and so on. The first metal material may be the material having great oxidation resistance, such as gold, platinum, palladium, rhodium, and so on. Before the aforementioned photolithography process and electroplating process using the first metal material, the structure located on the upper surface 31 of the insulating layer 30, including the grounding traces 41, the through holes 61 and the grooves 71, may, but not limited to, be plated with a seed layer of a material, such as titanium copper for example, by the aforementioned PVD process, thereby facilitating combination of the first metal material with the second metal material or the insulating layer 30. The seed layer will be mostly removed along with the photoresist after the electroplating process, but the part of the seed layer combined with the first metal material will be retained. Therefore, seed layers 72 are respectively provided between the signal trace 42 and the insulating layer 30, and between the conductive layers 62 of the conductive vias 60 and the grounding trace 41, the insulating layer 30 and the grounding layer 50, which are the part of the seed layer provided by the aforementioned PVD process.

After the grounding traces 41, the signal trace 42 and the conductive vias 60 are all formed and the aforementioned photoresist is removed, each of the grounding traces 41 and the grounding layer 50 may, but unlimited to, be covered by an oxidation resistant layer 73, so that the grounding traces 41 and the grounding layer 50 made of the second metal material are prevented from oxidation. Each of the oxidation resistant layers 73 may be made of a third metal material different from the first metal material and the second metal material. For example, the third metal material may be tin, and the oxidation resistant layers 73 may be formed by electroless tin plating. By choosing the material lower in electric conductivity than the second metal material but greater in oxidation resistance than the second metal material as the first metal material, it has no need of surface treatment performed to the signal trace 42 and the conductive layers 62 of the conductive vias 60. Besides, the first metal material is low in etch rate. For example, the ratio of the etch rate of the second metal material to the etch rate of the first metal material is larger than or equal to 100. Therefore, the widths or thicknesses of the signal trace 42 and the conductive layers 62 of the conductive vias 60 are not reduced by the etching process in the manufacturing process.

It is to be mentioned that each of the conductive layers 62 of the conductive vias 60 usually includes, but unlimited to include, a pad 63 protruding from the surface of the oxidation resistant layer 73 as shown in FIG. 8. The pad 63 is usually, but unlimited to, be circular-shaped. The pads 63 and the probe located on the same grounding trace 41 may, but unlimited to, be arranged on a same imaginary line. In the configuration as shown in FIG. 8, the pad 63 is lower in elevation than the pillar tip 87.

By the above-described configuration, the probe installation circuit board 20 of the present invention can be formed with thin copper traces, and the signal trace 42 and the conductive layers 62 of the conductive vias 60 can be formed by electroplating in the grooves provided with specific widths at specific positions by the photoresist produced in the photolithography process, such that it consumes low quantity of the first metal material and thus cost-saving, and it is easy to control the positions, widths and thicknesses of the signal trace 42 and the conductive layers 62 of the conductive vias 60 and bring low surface roughness. In addition, by controlling the depth of the grooves formed by the photoresist, the signal trace can be provided with small aspect ratio of depth to width, thereby beneficial to achieve the requirement of fine pitch.

As that in a third preferred embodiment of the present invention as shown in FIG. 6, each of the grounding traces 41 may be further partially provided thereon with a connecting layer 74 made of the first metal material. The connecting layers 74, the signal trace 41 and the conductive layers 62 of the conductive vias 60 are made by electroplating at the same time. Therefore, in the condition that the above-described PVD process has been performed before the electroplating process, a seed layer 72 as described above is provided between each of the connecting layers 74 and the grounding trace 41. As a result, the probe installation circuit board in this embodiment is adapted for the grounding probes (not shown) to be connected to the connecting layers 74 for improving the electric conductivity.

As that in a fourth preferred embodiment of the present invention as shown in FIG. 7, the trace structure 40 may further include a recess 43 recessed from the upper surface 31 of the insulating layer 30, and the signal trace 42 is disposed in the recess 43. In such configuration design, providing the recess 43 can reduce the thickness T of the part of the insulating layer 30 located below the signal trace 42. According to the formula of the affection of dielectric thickness on transmission loss:

$${Z}_{0} = \frac{87}{\sqrt{{ε}_{r} + 1.41}} ln [ \frac{5.98 h}{0.8 w + t} ] ,$$

wherein Z₀ is characteristic impedance, h is dielectric thickness, w is width of conductive wire, and t is thickness of conductive wire, under the precondition that the characteristic impedance is unchanged, the smaller the thickness T of the insulating layer 30 (i.e. the aforementioned dielectric thickness) is, the smaller the width W of the signal trace 42 (i.e. the aforementioned width of conductive wire) can be. By controlling the depth D of the recess 43, the thickness T of the part of the insulating layer 30 located below the signal trace 42 can be controlled, so that a required width W of the signal trace 42 can be attained. In this way, the probe device of the present invention can meet the limitative requirement of fine pitch between the tested pad positions of the device under test, and also meet the requirement of characteristic impedance.

In conclusion, the probe installation circuit board 20 provided by the present invention comprises an insulating layer 30, a grounding layer 50 disposed on a lower surface 32 of the insulating layer 30, a trace structure 40 disposed on an upper surface 31 of the insulating layer 30, and a plurality of conductive vias 60. The trace structure 40 includes two grounding traces 41, and a signal trace 42 located between the two grounding traces 41. Each of the grounding traces 41 is connected with the grounding layer 50 by at least one of the conductive vias 60. Each of the conductive vias 60 includes a through hole 61 penetrating through the grounding trace 41 and the insulating layer 30, and a conductive layer 62 disposed in the through hole 61 to electrically connect the grounding trace 41 with the grounding layer 50. The signal trace 42 and the conductive layers 62 of the conductive vias 60 are made of a first metal material. The grounding layer 50 and the grounding traces 41 are made of a second metal material different from the first metal material. As a result, the first metal material may be a metallic conductor having great oxidation resistance, so that the signal trace 42 and the conductive layers 62 of the conductive vias 60 have no need of surface treatment by nickel immersion gold and no reduction in width or thickness caused by etching in the manufacturing process. The original copper layer of a substrate can be used to form the grounding layer 50 and the grounding traces 41, so no additional copper layer should be made by electroplating. Therefore, thin copper traces can be formed. Besides, the signal trace 42 and the conductive layers 62 of the conductive vias 60 can be formed by electroplating in grooves provided with specific widths at specific positions by photoresist produced in the photolithography process, such that it consumes low quantity of the first metal material and thus cost-saving, and it is easy to control the positions, widths and thicknesses of the signal trace 42 and the conductive layers 62 of the conductive vias 60 and bring low surface roughness. In addition, by controlling the depth of the grooves formed by the photoresist, the signal trace 42 can be provided with small aspect ratio of depth to width, thereby beneficial to achieve the requirement of fine pitch.

Preferably, the insulating layer 30 may be a flexible board, so that the probe installation circuit board 20 is a flexible circuit board and can be made of the flexible substrate 10 mentioned in the description of the related art.

Preferably, the oxidation resistance of the first metal material may be greater than the oxidation resistance of the second metal material. Preferably, the electric conductivity of the first metal material may be lower than the electric conductivity of the second metal material. Preferably, the ratio of the etch rate of the second metal material to the etch rate of the first metal material may be larger than or equal to 100. For example, the first metal material may be gold, platinum, palladium or rhodium, and the second metal material may be copper, nickel or aluminum. As a result, the signal trace 42 and the conductive layers 62 of the conductive vias 60 have no need of surface treatment by nickel immersion gold and no reduction in width or thickness caused by etching in the manufacturing process. The original copper layer of a substrate can be used to form the grounding layer 50 and the grounding traces 41, so no additional copper layer should be made by electroplating. Therefore, thin copper traces can be formed.

Preferably, each of the grounding traces 41 may be covered by an oxidation resistant layer 73 to avoid oxidation. The oxidation resistant layer 73 may be made of a third metal material different from the first metal material and the second metal material. More preferably, the third metal material may be tin, and the oxidation resistant layer 73 may be made by electroless tin plating.

Preferably, each of the grounding traces 41 may be further partially provided thereon with a connecting layer 74 made of the first metal material, for the grounding probe 82 or 85 to be connected to the connecting layer 74, thereby improving the electric conductivity. More preferably, a seed layer 72 may be disposed between the connecting layer 74 and the grounding trace 41, thereby beneficial to the combination of the first metal material with the second metal material.

Preferably, the trace structure 40 may further include a recess 43 recessed from the upper surface 31 of the insulating layer 30, and the signal trace 42 is disposed in the recess 43, so that the requirements of fine pitch and characteristic impedance can be met.

Preferably, seed layers 72 may be respectively disposed between the signal trace 42 and the insulating layer 30, and between the conductive layers 62 of the conductive vias 60 and the grounding trace 41, the insulating layer 30 and the grounding layer 50, thereby beneficial to the combination of the first metal material with the second metal material or the insulating layer 30.

Preferably, an end of each of the grounding traces 41 and the signal trace 42 is adapted to be electrically connected with a respective probe 81 or 82, and the other end of each of the grounding traces 41 and the signal trace 42 is adapted to be electrically connected to a tester 83, so that test signal can be transmitted between the probes 81 and 82 and the tester 83.

In addition, the probe device 91 provided by the present invention includes the aforementioned probe installation circuit board 20, and probes 81 and 82 disposed on the grounding traces 41 and the signal trace 42 respectively. An end of each of the grounding traces 41 and the signal trace 42 is electrically connected with the respective probe 81 or 82, and the other end of each of the grounding traces 41 and the signal trace 42 is electrically connected with a tester 83, so that test signal can be transmitted between the probes 81 and 82 and the tester 83.

Preferably, each of the probes 81 and 82 may be a cantilever probe partially fixed to the probe installation circuit board 20 and partially extending out of the probe installation circuit board 20 transversely.

Preferably, each of the probes 84 and 85 includes a pillar tip 87 extending vertically.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A probe installation circuit board for a probe card, the probe installation circuit board comprising:
an insulating layer having an upper surface and a lower surface;
a grounding layer disposed on the lower surface of the insulating layer;
a trace structure disposed on the upper surface of the insulating layer, the trace structure comprising two grounding traces and a signal trace located between the two grounding traces; and
a plurality of conductive vias, each of the grounding traces being connected with the grounding layer by at least one of the conductive vias, each of the conductive vias comprising a through hole penetrating through the grounding trace and the insulating layer, and a conductive layer disposed in the through hole to electrically connect the grounding trace with the grounding layer;
wherein the signal trace and the conductive layers of the conductive vias are made of a first metal material; the grounding layer and the grounding traces are made of a second metal material different from the first metal material.

2. The probe installation circuit board as claimed in claim 1, wherein the insulating layer is a flexible board.

3. The probe installation circuit board as claimed in claim 1, wherein an oxidation resistance of the first metal material is greater than an oxidation resistance of the second metal material.

4. The probe installation circuit board as claimed in claim 1, wherein an electric conductivity of the first metal material is lower than an electric conductivity of the second metal material.

5. The probe installation circuit board as claimed in claim 1, wherein a ratio of an etch rate of the second metal material to an etch rate of the first metal material is larger than or equal to 100.

6. The probe installation circuit board as claimed in claim 1, wherein the first metal material is one of gold, platinum, palladium and rhodium.

7. The probe installation circuit board as claimed in claim 1, wherein the second metal material is one of copper, nickel and aluminum.

8. The probe installation circuit board as claimed in claim 1, wherein each of the grounding traces is covered by an oxidation resistant layer; the oxidation resistant layer is made of a third metal material different from the first metal material and the second metal material.

9. The probe installation circuit board as claimed in claim 8, wherein the third metal material is tin; the oxidation resistant layer is made by an electroless tin plating process.

10. The probe installation circuit board as claimed in claim 1, wherein each of the grounding traces is partially provided thereon with a connecting layer made of the first metal material.

11. The probe installation circuit board as claimed in claim 10, wherein a seed layer is disposed between the connecting layer and the grounding trace.

12. The probe installation circuit board as claimed in claim 1, wherein the trace structure further comprises a recess recessed from the upper surface of the insulating layer; the signal trace is disposed in the recess.

13. The probe installation circuit board as claimed in claim 12, wherein seed layers are respectively disposed between the signal trace and the insulating layer, and between the conductive layers of the conductive vias and the grounding traces, the insulating layer and the grounding layer.

14. The probe installation circuit board as claimed in claim 1, wherein seed layers are respectively disposed between the signal trace and the insulating layer, and between the conductive layers of the conductive vias and the grounding traces, the insulating layer and the grounding layer.

15. The probe installation circuit board as claimed in claim 1, wherein an end of each of the grounding traces and the signal trace is adapted to be electrically connected with a respective probe; the other end of each of the grounding traces and the signal trace is adapted to be electrically connected to a tester.

16. A probe device comprising:
a probe installation circuit board as claimed in claim 1; and
three probes disposed on the grounding traces and the signal trace respectively;
wherein an end of each of the grounding traces and the signal trace is electrically connected with the respective probe; the other end of each of the grounding traces and the signal trace is electrically connected with a tester.

17. The probe device as claimed in claim 16, wherein each of the probes is a cantilever probe partially fixed to the probe installation circuit board and partially extending out of the probe installation circuit board transversely.

18. The probe device as claimed in claim 16, wherein each of the probes comprises a pillar tip extending vertically.
